(19) United States
(12) Patent Application Publication
(10) Pub. No.: US 2024/0222478 A1
(43) Pub. Date: Jul. 4, 2024

(54) REVERSE CONDUCTING LATERAL INSULATED-GATE BIPOLAR TRANSISTOR

(71) Applicant: CSMC TECHNOLOGIES FAB2 CO., LTD., Wuxi (CN)

(72) Inventors: Sen ZHANG, Wuxi (CN); Yan GU, Wuxi (CN); Siyu CHEN, Wuxi (CN)

(21) Appl. No.: 18/558,422

(22) PCT Filed: Jan. 24, 2022
(86) PCT No.: PCT/CN2022/073350

§ 371 Date: Nov. 1, 2023

(30) Foreign Application Priority Data
May 31, 2021 (CN) 202110600489.6

(51) Int. Cl. H01L 29/739; H01L 27/07; H01L 29/423; H01L 29/866

(52) U.S. Cl. CPC H01L 29/7394; H01L 27/0727; H01L 29/4236; H01L 29/866

(57) ABSTRACT

A reverse conducting lateral insulated-gate bipolar transistor includes a drift region formed on a substrate, a gate located on the drift region, an emitter region located on the drift region and close to one side of the gate, and a collector region located on the drift region and away from one side of the gate. Two or more N-well regions arranged at intervals are provided on the side of the drift region where the collector region is located. A P-well region is provided between the two or more N-well regions arranged at intervals; a P+ contact region is provided on the N-well region; an N+ contact region is provided on the P-well region; both the P+ contact region and the N+ contact region are conductively connected to a collector lead-out end.

### CROSS REFERENCE TO RELATED APPLICATION

The present application claims priority to Chinese Patent Application with No. 202110600489.6, entitled “Reverse Conducting Lateral Insulated-Gate Bipolar Transistor”, and filed on May 31, 2021, the content of which is expressly incorporated herein by reference in its entirety.

### TECHNICAL FIELD

The present disclosure relates to the field of semiconductor device technology, and particularly to a reverse conducting lateral insulated-gate bipolar transistor.

### BACKGROUND

The statement herein merely provides background information related to the present disclosure and does not definitely constitute exemplary techniques.

The lateral insulated-gate bipolar transistor (LIGBT) is a transistor that combines the advantages of a MOS transistor and a bipolar transistor. The silicon on insulator (SOI) technique is widely used in the manufacture of power integrated circuits due to the ideal dielectric isolation performance thereof. The SOI-LIGBT device is a LIGBT device manufactured based on the SOI technique.

Intelligent power modules (IPM) are widely used in electric machine drivers or motor drivers. Fully integrated SOI-LIGBT is often used under the medium power conditions as a power switching device, and the LIGBT parallel high-voltage freewheeling diode (FWD) is the most classic switching device structure. When the LIGBT is turned on forward, the hole injection forms a large current conduction, which drives the inductive load to operate normally. When the LIGBT is turned off, the inductive load needs a loop to continue the current because the current cannot change suddenly. At the moment, the parallel FWDs play the role of freewheeling. When the gate of LIGBT is turned on in the next stage, the FWD returns to the off state after the reverse recovery, and an operating period ends.

In the design of the integrated power module, since LIGBT and FWD are two different types of devices, a high degree of matching is required to ensure the normal switching characteristics during the operation. Therefore, a relationship between E_{off} of the LIGBT when turned off and trr of the FWD during the reverse recovery should be considered when devices are designed, otherwise it is easy to cause an excessive loss and a longer delay, which may affect the reliability of the LIGBT module.

In order to reduce the turn-off loss, the patent document CN111816699A proposes an adaptive SOI LIGBT device, which mainly integrates a Zener diode. Since the Zener diode can be subjected to adaptive reverse breakdown and conduction as the collector voltage rises, an additional path for quickly extracting the holes stored in the drift region is provided in the turn-off process. In this patent document, it is also mentioned that the collector structure is a collector NMOS structure, and the N-type buffer layer is further provided with a second P-type trench region, a P+ trench potential region, an N+ collector region, and a collector groove gate. The P+ potential region and the P+ trench potential region are short-circuited, so that the potential difference between the collector and the P+ trench potential region is also smaller, an inversion layer cannot be formed in the second P-type trench region, which leads to the blocking of the conductive path between the N+ collector region and the N-type buffer layer, and the device cannot enter the unipolar conduction mode, thereby eliminating the snap-back effect when the device is turned on forward. However, the structure of this patent document introduces a Zener diode, since the Zener diode generally has a Zener-type tunnel breakdown, when it serves as a freewheeling diode in a reverse-conducting LIGBT, it is relatively limited when used under the high voltage or ultra-high voltage conditions during the reverse breakdown: and although the Zener diode in this patent document has a certain effect in suppressing the snap-back effect of forward conduction, the faster recovery characteristics cannot be achieved; due to the collector structure thereof, the turn-off rate of the switch in the reverse recovery stage of the LIGBT still needs to be improved.

### SUMMARY

According to various embodiments of the present disclosure, a reverse conducting lateral insulated-gate bipolar transistor is provided.

A reverse conducting lateral insulated-gate bipolar transistor includes: a drift region formed on a substrate, a gate located on the drift region, an emitter region located on the drift region and adjacent to a side of the gate, and a collector region located on the drift region and away from a side of the gate:
two or more N-well regions arranged at intervals are provided on a side of the drift region on which the collector region is located;
a P-well region is provided between two adjacent N-well regions of the two or more N-well regions arranged at intervals;
a P+ contact region is provided on a N-well region;
an N+ contact region is provided on the P-well region; and
both the P+ contact region and the N+ contact region are electrically connected to a collector leading-out terminal.

In an optional embodiment, the two or more N-well regions arranged at intervals at least includes a first N-well region and a second N-well region, the P-well region at least includes a first P-well region provided between the first N-well region and the second N-well region, an area of the first N-well region is equal to an area of the second N-well region, and the first N-well region and the second N-well region are symmetrically arranged with respect to the first P-well region.

In an optional embodiment, the N+ contact region is enclosed by the P-well region in a direction parallel to a plane on which the substrate is located.

In an optional embodiment, the N+ contact region includes a first portion and a second portion, the first portion includes a sidewall portion and a bottom portion, the sidewall portion extends in a direction perpendicular to a plane on which the substrate is located, the bottom portion is connected to the sidewall portion at a side of the bottom portion close to the substrate, the second portion is connected to the sidewall portion at a side of the second portion away from the substrate, and a depth of the sidewall portion is greater than a depth of the second portion.

In an optional embodiment, the depth of the sidewall portion is greater than a depth of the P+ contact region.

In an optional embodiment, a trench is formed in the P-well region, and the sidewall portion and the bottom portion of the first portion are formed by doping a side surface and a bottom surface of the trench respectively.

In an optional embodiment, a filling structure is formed in the trench, and the second portion is located on the filling structure.

In an optional embodiment, a material of the filling structure includes an insulating material and/or polysilicon.

In an optional embodiment, there exists a plurality of P-well regions, a plurality of N+ contact regions are respectively located in the plurality of P-well regions, and the plurality of N+ contact regions are arranged alternatively with the P+ contact regions in a direction parallel to a plane where the substrate is located.

In an optional embodiment, the two or more N-well regions provided at intervals are arranged alternatively with the plurality of P-well regions in a direction parallel to a plane where the substrate is located.

The details of one or more embodiments of the present disclosure are set forth with reference to the accompanying drawings and the description below. Other features, purposes and advantages of the present disclosure will be obvious from the specification, drawings and claims.

### BRIEF DESCRIPTION OF THE DRAWINGS

In order to more clearly describe the technical solution in the embodiments or exemplary technologies of the present disclosure, accompanying drawings that need to be used in the description of the embodiments or exemplary technologies will be briefly introduced. Obviously, the accompanying drawings in the following description are merely some embodiments of the present disclosure. Those of ordinary skill in the art can obtain drawings of other embodiments based on these drawings without creative work.

FIG. 1 is a schematic cross-sectional view of a common lateral insulated-gate bipolar transistor.

FIG. 2 is a schematic cross-sectional view of a reverse conducting lateral insulated-gate bipolar transistor according to a related embodiment.

FIG. 3 is a schematic cross-sectional view of a reverse conducting lateral insulated-gate bipolar transistor according to an embodiment I.

FIG. 4 is a schematic cross-sectional view of a reverse conducting lateral insulated-gate bipolar transistor according to an embodiment II.

FIGS. 5a-5c are schematic top views of a collector region of a reverse conducting lateral insulated-gate bipolar transistor according to an optional embodiment.

### DETAILED DESCRIPTION

In order to facilitate the understanding of the present disclosure, the present disclosure will be described more comprehensively below with reference to the relevant accompanying drawings. Preferred embodiments of the present disclosure are shown in the drawings. However, the present disclosure can be implemented in many different forms and is not limited to the embodiments described herein. Rather, the purpose of providing these embodiments is to make the present disclosure more thorough and comprehensive.

Unless otherwise defined, all technical and scientific terms used herein have the same meaning as commonly understood by one of ordinary skill in the technical field to which the present disclosure belongs. The terms used herein in the specification are merely for the purpose of describing specific embodiments, and are not intended to limit the present disclosure.

It should be appreciated that when an element or a layer is referred to as being “on”, “adjacent to”, “connected to”, or “coupled to” another element or layer, it may be directly on, adjacent to, connected to, or coupled to the other element or layer: or there may exist an intermediate element or layer. Conversely, when an element is referred to as being “directly on”, “in contact with”, “directly connected to” or “directly coupled to” another element or layer, there does not exist is an intermediate element or layer. It should be appreciated that although the terms such as first, second, third, etc., may be utilized to describe various elements, components, regions, lavers, doping types and/or portions, these elements, components, regions, layers, doping types and/or portions should not be limited by these terms. These terms are merely utilized to distinguish one element, component, region, layer, doping type or portion from another element, component, region, layer, doping type or portion. Thus, a first element, component, region, layer, doping type or portion discussed below can be termed a second element, component, region, layer or portion without departing from the teaching of the present disclosure.

Spatial relation terms such as “under”, “beneath”, “below”, “down”, “above”, “on” and the like may be used herein to describe the relationship between one element or feature and other elements or features shown in the drawings. It should be appreciated that the spatial relation terms further include different orientations of the device in use and operation in addition to the orientations depicted in the figures. For example, if the device in the figures is turned over, which is described as that elements or features described as “below” or “under” or “beneath” other elements or features would then be oriented “above” the other elements or features. Thus, the exemplary terms “under” and “below” may include both orientations of up and down. In addition, the device may be otherwise oriented (e.g., rotated 90 degrees or at other orientations), and the spatial descriptors used herein are interpreted accordingly.

When used herein, the singular forms “a”, “an” and “the/said” may also include the plural forms unless the context clearly dictates otherwise. It should also be appreciated that the terms “comprising/including” or “having”, etc., specify the presence of stated features, integers, steps, operations, components, portions or combinations thereof, but do not exclude the possibility of existing or adding one or more other features, integers, steps, operations, components, portions or combinations thereof. Meanwhile, in the specification, the term “and/or” includes any and all combinations of the related listed items.

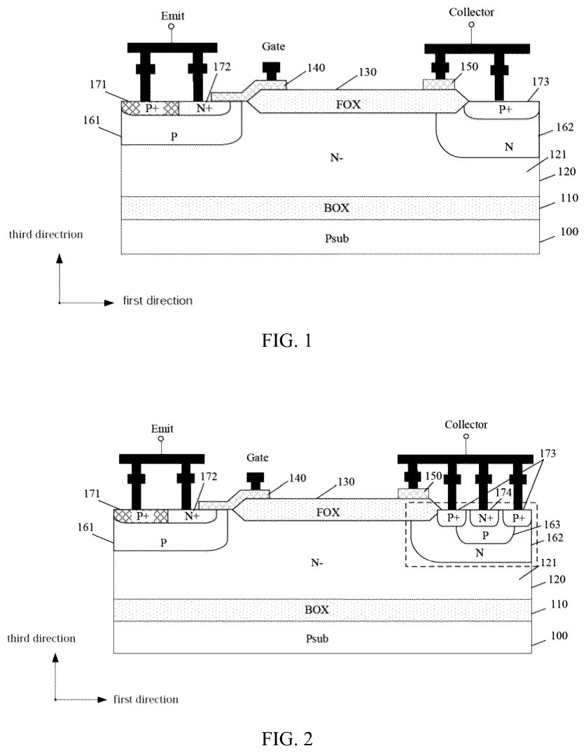

First, referring to FIG. 1, which is a schematic cross-sectional view of a common lateral insulated-gate bipolar transistor. As shown in the figure, the lateral insulated-gate bipolar transistor includes: an SOI substrate (including a bottom silicon layer 100, a buried oxide layer 110 and a top silicon layer 120), a drift region 121 located in the top silicon layer 120, a field oxide layer 130, a gate 140, a polysilicon field plate 150 at a collector, an emitter region located on the drift region 121 and close to a side of the gate, and a collector region located on the drift region 121 and away from a side of the gate. The emitter region is provided with a channel region 161, and the channel region 161 is specifically a P-well region, and serves as a conductive channel of a lateral MOS in the LIGBT. A substrate ohmic contact region 171 and a source ohmic contact region 172 are provided on the channel region 161, and both the substrate ohmic contact region 171 and the source ohmic contact region 172 are electrically connected to an emitter leading-out terminal. The collector region is provided with an N-type buffer region (hereinafter referred to as N-well region 162), and a P+ contact region 173 is arranged on the N-well region 162. Both the P+ contact region 173 and the polysilicon field plate 150 are electrically connected to the collector leading-out terminal.

In the above structure, the LIGBT needs to be connected to the FWD in parallel. When the LIGBT is turned on forward, hole injection forms large current conduction, which drives the inductive load to operate normally. When the LIGBT is turned off, the inductive load needs a loop to continue the current because the current cannot change suddenly. At the moment, the FWD connected in parallel plays the role of freewheeling. When the gate of LIGBT is turned on in the next stage, the FWD returns to the cut-off state after the reverse recovery, and an operating period ends. However, since the LIGBT and FWD are two different types of devices, a high degree of matching is required to ensure normal switching characteristics during the operation. Therefore, how to integrate the independent FWD and LIGBT has become an important research direction in this field.

In view of the above structure, since the collector is P+(referring to the P+ contact region 173 in FIG. 1), the LIGBT has no current discharge path and the current can only flow out from the parallel diode (i.e., FWD). The present disclosure firstly provides a related embodiment, the related embodiment provides a reverse conducting lateral insulated-gate bipolar transistor. By improving the structure of the collector of the LIGBT, the characteristics of the LIGBT during the switching are improved. Referring to FIG. 2 for details. As shown in the figure, in this related embodiment, in addition to providing the P+ contact region 173 in the N-well region 162, an N+ contact region 174 is further provided in the N-well region 162, that is, the N+ contact region is added in the collector region. Further, a lower end of the N+ contact region 174 is surrounded by the P-well region 163. Accordingly, when the LIGBT is normally turned on, holes in the P+ contact region 173 are injected into the N-well region 162 and the drift region 121 to generate a conductivity modulation effect, and the current rises sharply after the PNP transistor is triggered. And then the LIGBT enters the forward conduction operation. At the moment, the N+ contact region 174 and the P-well region 163 are in a reverse bias state, and electrons cannot pass through a depletion layer to form an LDMOS, so that the normal turn-on operation is not affected when the LIGBT is turned on forward. When the LIGBT is turned off reversely, the collector of the LIGBT loses the voltage and becomes zero potential. At the moment, the inductive load current driven cannot change suddenly and flows in through the P+ of the emitter (referring to the substrate ohmic contact region 171 in FIG. 2). Compared to the conventional structure in the prior art, due to the existence of the N+ contact region 174 in the structure provided by the related embodiment, there is a current path that can be passed through and back to the coil during the freewheeling, so that there is no need to additionally connect the FWD in parallel for freewheeling. A chip area can be greatly saved when the module operates, and the reliability of the LIGBT is also improved.

However, in the relevant embodiment shown in FIG. 2, the P+ contact region 173, the N+ contact region 174, and the P-well region 163 are all arranged in the same N-well region 162. The minority carrier, i.e., hole, has a higher barrier to transit during the reverse recovery of the LIGBT, and the turning-off rate in the reverse recovery stage of the LIGBT needs to be improved.

Based on this, the present disclosure provides the following embodiments. The reverse conducting lateral insulated-gate bipolar transistor includes: a drift region formed on a substrate, a gate located on the drift region, an emitter region located on the drift region and close to a side of the gate, and a collector region located on the drift region and away from a side of the gate.

Two or more N-well regions arranged at intervals are provided on a side of the drift region where the collector region is located.

A P-well region is provided between two adjacent N-well regions of the two or more N-well regions arranged at intervals.

A P+ contact region is provided in the N-well region.

An N+ contact region is provided in the P-well region.

Both the P+ contact region and the N+ contact region are electrically connected to the collector leading-out terminal.

It can be appreciated that, compared to the prior art, in the embodiments of the present disclosure, the structure of the collector region of the LIGBT is improved, which not only makes the improved device structure unnecessary to additionally connect to the FWD in parallel for freewheeling, but also greatly saves the chip area when the module operates, thereby improving the reliability of the LIGBT. Further, due to the arrangement of N-well regions at intervals, the P-well region is provided between the spaced N-well regions, thereby further improving the turning-off rate of the LIGBT in the reverse recovery stage, and improving the switching characteristics of the entire device.

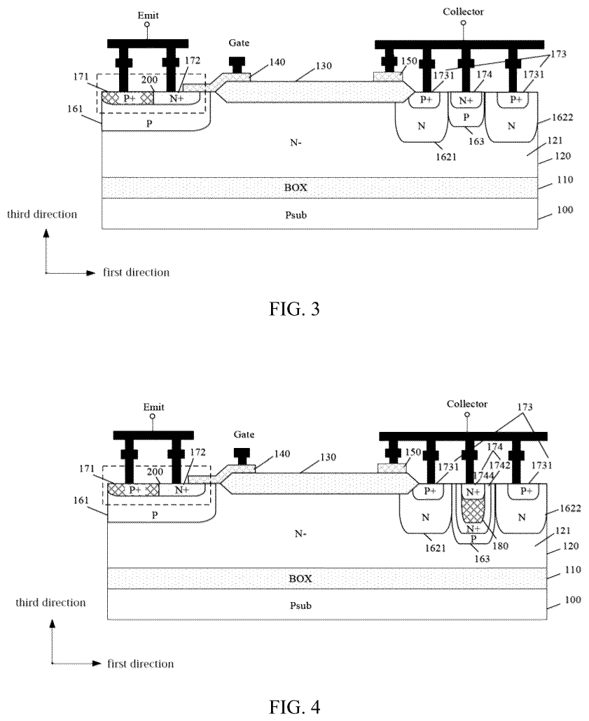

Firstly, the embodiment of the present disclosure will be further illustrated with reference to FIG. 3. FIG. 3 is a schematic cross-sectional view of a reverse conducting lateral insulated-gate bipolar transistor provided in the embodiment I of the present disclosure. As shown in the figure, the reverse conducting lateral insulated-gate bipolar transistor includes a SOI substrate, i.e., includes a bottom silicon layer 100, a buried oxide layer 110, and a top silicon layer 120.

The bottom silicon layer 100 has a first conductivity type, specifically for example, the P-type, that is, the bottom silicon layer 100 is a P-type substrate (Psub). The material thereof is silicon. Of course, the embodiment of the present disclosure is not limited thereto, materials commonly used in this field, such as silicon carbide, gallium arsenide, indium phosphide or silicon germanium, etc., can also be used as the material of the bottom substrate of the SOI substrate in the embodiment of the present disclosure.

The buried oxide layer 110 is located on the bottom silicon layer 100 and the material thereof is usually the silicon oxide, such as silicon dioxide. The buried oxide layer 110 is generally named BOX in terms of function, and is specifically an insulating layer, and the material thereof may also be other insulating materials not limited to the silicon dioxide.

The top silicon layer 120 is located on the buried oxide layer 110, which specifically may be an epitaxial layer with a second conductivity type, and serves as a layer for manufacturing devices. The top silicon layer 120 serves as a drift region (indicated by the drift region 121 in the figure) in the LIGBT device. Specifically, the second conductivity type may be N-type. The conductivity type of the drift region is opposite to that of the bottom silicon layer 100. The drift region 121 is specifically an N-region. The material of the top silicon layer 120 is silicon. Of course, the embodiment of the present disclosure is not limited thereto, and materials commonly used in this field, such as silicon carbide, gallium arsenide, indium phosphide or silicon germanium, etc., can also be used as the material of the top substrate of the SOI substrate in the embodiment of the present disclosure.

The field oxide layer 130 is formed on the drift region 121, and the material of the field oxide layer 130 may be silicon oxide, such as silicon dioxide. The field oxide layer 130 is a field region of the LIGBT, serving as a lateral isolation of the device.

A gate 140 is formed on the field oxide layer 130, and the material of the gate 140 is, for example, polysilicon, and serves as a gate of the LIGBT.

A polysilicon field plate 150 at a collector is further formed on the field oxide layer 130, which serves as a polysilicon field plate at the collector of the LIGBT.

Both the channel region 161 and the N-well region 162 are located in the drift region 121, and both are spaced in a first direction indicated in the figure. The channel region 161 is located on a side close to the gate 140. The channel region 161 has the first conductivity type, specifically, such as a P-well. The channel region 161 forms a conductive channel of the lateral MOS. The N-well region 162 is located on a side away from the gate 140. The N-well region 162 is located in the collector region of the LIGBT and serves as an N-type buffer layer of the LIGBT to prevent breakdown.

A substrate ohmic contact region 171 having the first conductivity type and a source ohmic contact region 172 having the second conductivity type are provided in the channel region 161. The substrate ohmic contact region 171 is specifically a P+ type region, which is drawn out as the substrate. The source ohmic contact region 172 is specifically an N+ type region, serving as a source ohmic contact of the MOS. The source ohmic contact region 172 is in contact with the channel region 161 on a side facing the gate 140 to induce a channel in the channel region 161.

On the side of the drift region 121 where the collector region is located (as indicated by a dotted line box in the figure) is provided with two or more N-well regions arranged at intervals (a first N-well region 1621 and a second N-well region 1622 in FIG. 3 shown as an example). The N-well regions serve as buffer regions for the LIGBT. However, in the reverse conducting LIGBT provided in the embodiment, the buffer region is divided into two or more N-well regions arranged at intervals, to independently serve as a LIGBT unit.

A P+ contact region 173 is provided in the N-well region, and the P+ contact region 173 can also be referred to as a collector ohmic contact region, which serves as a collector ohmic contact of the LIGBT and provides electrode extraction. Specifically, each N-well region can be provided with independent P+ contact regions. Each P+ contact region can be located in each corresponding N-well region as shown in FIG. 3, and a side and a bottom portion of the P+ contact region are enclosed by the N-well region. Each P+ contact region can also be located in each corresponding N-well region, and only the bottom portion is enclosed by the N-well region.

A P-well region 163 is provided between two adjacent N-well regions of the two or more N-well regions arranged at intervals (for example, between the first N-well region 1621 and the second N-well region 1622). The P-well region 163 is a P-well which can be turned on or off forward.

An N+ contact region 174 is provided on the P-well region 163. The N+ contact region 174 serves as an N+ leading-out terminal of the collector of the LIGBT, and is a cathode of a diode generated during the reverse conduction.

As shown in the figure, both the P+ contact region 173 and the N+ contact region 174 are electrically connected to the collector leading-out terminal.

In such a manner, the emitter, the collector, and the gate of the LIGBT are shown in the figure.

Here, a direction perpendicular to a plane where the substrate is located is defined as a third direction, that is, a stacking direction of each layer structure. First and second directions perpendicular to each other are defined in a plane parallel to the substrate.

In the embodiment of the present disclosure, the entire N-well region 162 in the related embodiment is divided to form several independent ones (FIG. 3 merely schematically shows two N-well regions. In practice, there may exist at least two spaced N-well regions), so that not only no additional FWD connected in parallel is needed for freewheeling, but also the turning-off rate in the LIGBT reverse recovery stage can be improved.

Here, it should be appreciated that at least a part of the N+ contact region 174 (specifically, such as a portion other than the upper surface) is directly in contact with at least a part of the P-well region 163, and a PN junction is formed therebetween, and is specifically P/N+. At least a part of the P-well region 163 (at least including a portion where the lower surface is located) is directly in contact with the drift region 121. A PN junction is formed therebetween, and is specifically P/N−. A potential barrier between the P-well region 163 and the drift region 121 is apparently lower than a potential barrier between the P-well region 163 and the N-well region 162 in the related embodiment.

Please continue to refer to FIG. 3, the two or more N-well regions arranged at intervals at least include the first N-well region 1621 and the second N-well region 1622. The P-well region 163 at least includes the first P-well region provided between the first N-well region 1621 and the second N-well region 1622 (since there is only one P-well region in the cross-sectional view of FIG. 3, reference can be made to the P-well region 163 in the figure). The area of the first N-well region 1621 is equal to the area of the second N-well region 1622. The first N-well region 1621 and the second N-well region 1622 are symmetrically arranged with respect to the first P-well region.

It should be appreciated that, since the area of the first N-well region is equal to the area of the second N-well region, the first N-well region and the second N-well region are symmetrically arranged with respect to the first P-well region. When the device is turned on forward, the current can flow more evenly to each P+ contact region of the collector region, so that the conduction characteristic of the device is more stable. Otherwise, if the arrangement is asymmetrical and non-uniform, it is easy to cause the device to turn on before going through the PNP stage, the entire device loses the conductance modulation effect and becomes an LDMOS. The same problem may also occur during the reverse freewheeling. If the arrangement is non-uniform, the freewheeling characteristic of the reverse conducting diode decreases, and the resistance is increased and is not easy to recover quickly. While the first N-well region and the second N-well region have the same area and arranged symmetrically, the freewheeling characteristic is better and the recovery is faster.

The first N-well region 1621, the first P-well region, and the second N-well region 1622 are sequentially arranged in, for example, the first direction. The first direction is also the direction from the emitter region to the collector region. The first N-well region 1621, the first P-well region and the second N-well region 1622 may be connected in sequence to save the area.

In the direction parallel to the plane where the substrate is located, the N+ contact region 174 is enclosed by the P-well region 163. It can be appreciated that after the P-well region 163 encloses the N+ contact region 174, there is no snap-back phenomenon like the common LIGBTs at the beginning of the turn-on of the LIGBT (that is, when the forward voltage reaches a certain level, the current increases but the voltage decreases). Since the N+ contact region 174 does not participate in the operation when the LIGBT is turned on forward, and operates as a penetrating LIGBT. The forward conduction voltage decreases, so that the N+ contact region 174 has less Vcesat characteristics. Meanwhile, part of the minority carriers passes through the PN junction potential barrier formed by the N+ contact region 174 and the P-well region 163 and recombine with the N+ contact region 174 during the turn-off, thereby reducing LIGBT tailing phenomenon and the turn-off loss.

FIG. 4 is a schematic cross-sectional view of a reverse conducting lateral insulated-gate bipolar transistor provided in an embodiment II. As shown in the figure, in the embodiment, the N+ contact region 174 includes a first portion 1742 and a second portion 1744. The first portion 1742 includes a sidewall portion and a bottom portion. The sidewall portion extends in a direction perpendicular to the plane where the substrate is located, and the bottom portion is connected to the sidewall portion at a side of the bottom portion close to the substrate. The second portion 1744 is connected to the sidewall portion at a side of the second portion 1744 away from the substrate. A depth of the sidewall portion is greater than a depth of the second portion 1744.

Here, the second portion 1744 and the bottom portion of the first portion 1742 can serve as a lateral N+ leading-out terminal of the collector of the LIGBT. The sidewall portion of the first portion 1742 can serve as a vertical N+ leading-out terminal of the collector of the LIGBT. The above leading-out terminals are cathodes of the diode generated during the reverse conduction.

The embodiment II further achieves the following advantages. On the one hand, the contact area of N+ is increased in the collector region, i.e., the lateral N+ and the vertical N+, and then the conduction contact is performed on the upper surface of the N+ contact region. Since the contact area of N+ is large, so that the role of N+ as a reverse diode can be maximized, which greatly enhances the reverse freewheeling capability of the reverse conducting LIGBT. Meanwhile, during the reverse recovery of the diode, the number of minority carrier, i.e., holes, moving along the sidewall portion is greater than the number of minority carrier, i.e., holes, moving along the upper surface, so that the movement path of minority carrier is shorter, which can further improve the efficiency of hole recombination, increase the reverse recovery time trr, and reduce a peak current Irr during the reverse recovery. On the other hand, the area of the LIGBT collector region can also be greatly reduced. Since the pitch of the structure forming the first portion 1742 (specifically, a trench structure) can be designed to be very small, and the area of N+ injection may not be reduced in the case of the same depth, so that the overall area of LIGBT can be reduced by reducing the area of the collector region.

In the actual manufacture process, the above-mentioned first portion 1742 can be formed by first forming a trench in the P-well region 163, doping the side surface and the bottom surface of the trench, and then filling the trench, and forming the second portion 1744 on the top portion of the trench. The doping is performed by, for example, ion injection and other processes.

In the device structure, a trench is formed in the P-well region 163. The sidewall portion and the bottom portion of the first portion 1742 are formed by doping the side surface and the bottom surface of the trench respectively. In such a manner, the cross-sectional shape of the first portion 1742 may be similar to a shape of the trench formed, such as a U-shape.

A filling structure 180 is formed in the trench. The second portion 1744 is located on the filling structure 180.

The material of the filling structure 180 includes an insulating material and/or polysilicon. In an optional embodiment, the material of the filling structure 180 includes an insulating material, such as silicon oxide, and the insulating material can be further filled with the polysilicon, thereby forming the second portion 1744 in the polysilicon. In another alternative embodiment, the trench can be directly filled with the polysilicon, and the second portion 1744 is formed on the upper surface of the polysilicon.

Thus, at least a filling material is included between the first portion 1742 and the second portion 1744, that is, inside the N+ contact region 174.

In the embodiment, the depth of the sidewall portion of the first portion 1742 is, for example, greater than the depth of the P+ contact region 173.

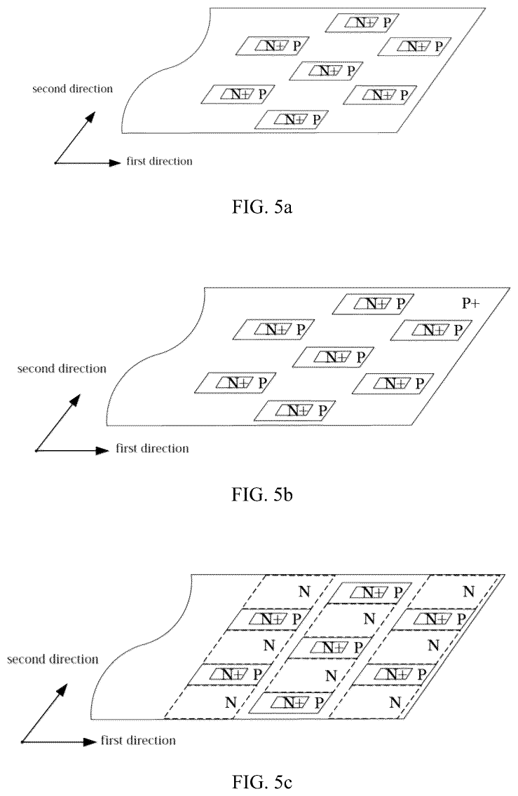

FIGS. 5a-5c are schematic top views of a collector region of a reverse conducting lateral insulated-gate bipolar transistor in alternative embodiments.

Firstly, referring to FIG. 5a. As shown in the figure, there may exist a plurality of P-well regions, and a plurality of N+ contact regions are respectively located in the plurality of P-well regions. The plurality of N+ contact regions are arranged alternatively with the P+ contact regions in a direction parallel to a plane where the substrate is located.

Here, although the P+ contact regions are not explicitly shown, it can be appreciated that there is a P+ contact region between two adjacent N+ contact regions in no matter the first direction or the second direction. Further, there is a P+ contact region between two adjacent N+ contact regions, and there is an N+ contact region between two adjacent P+ contact regions.

However, FIG. 5b shows a possible situation, that is, the P+ contact regions are located among various N+ contact regions, and specifically are located among various P-well regions. The P+ contact regions are connected as a whole. The P-well regions and the N+ contact regions in the corresponding P-well regions are arranged like islands in the P+ contact region.

It should be appreciated that compared to a grid layout (or a matrix array arrangement), the alternative arrangement structure is more adapted to a high current density. The large current LIGBT is prone to the snap-back phenomenon in the emitter region, and the alternative arrangement of N+ and P+ can greatly eliminate conditions for the snap-back of the device, so that the PN junction is not easy to conduct, thereby improving the safe operating region of the LIGBT.

Since FIG. Sa and FIG. 5b do not show the situation inside the device (inside the top silicon layer 120), the dotted line in FIG. 5c indicates the N-well region inside the top silicon layer 120. As shown in FIG. 5c, two or more N-well regions arranged at intervals may be alternately distributed with the plurality of P-well regions in the direction parallel to the plane where the substrate is located.

In a specific embodiment, in the first direction, the plurality of N-well regions and the plurality of P-well regions are arranged in a manner of “N-well region_P-well region_N-well region . . . ” in the second direction, and the plurality of N-well regions and the multiple P-well regions are also arranged in the manner of “N-well region_P-well region_N-well region . . . ”.

It can be appreciated that even in the structure shown in FIG. 5b where the P+ contact regions are connected as a whole on the upper surface of the top silicon layer 120, various N-well regions are still arranged at intervals under the P+ contact region.

The N-well region may be adjacent to the P-well region. Of course, the present disclosure does not exclude the situation that there is a gap therebetween. On the upper surface of the top silicon layer 120, the P-well region should have an exposed portion, while the N-well region may not be exposed.

The upper surface mentioned in each embodiment of the present disclosure should be understood as the surface of the corresponding structure away from the substrate. Accordingly, the lower surface should be understood as the surface of the corresponding structure adjacent to the substrate.

It should be noted that embodiments of the present disclosure should not be limited to the particular shapes of regions shown herein but may include deviations in shapes that result, for example, from manufacture techniques. For example, an injection region illustrated as a rectangle may, typically, have rounded or curved features and/or an injection concentration gradient at edges thereof rather than a binary change from the injection region to the non-injection region. Similarly, the buried region formed by injection may result in some injection in a region between the buried region and the surface through which the injection is performed. Thus, the regions shown in the figures are schematic in essence and the shapes thereof do not indicate the actual shapes of regions on the device and are not intended to limit the scope of the present disclosure.

In the description of the specification, descriptions referring to the terms “in an embodiment”, “in an optional embodiment”, “in other embodiments” and the like mean specific features, structures, materials, or features described in connection with the embodiments or examples, are included in at least one embodiment or example of the present disclosure. In the specification, schematic descriptions of the above terms do not definitely refer to the same embodiment or example.

The technical features of the above-mentioned embodiments can be combined arbitrarily. In order to make the description concise, not all possible combinations of the various technical features in the above-mentioned embodiments are described. However, as long as there is no contradiction in the combinations of these technical features, all should be considered as the scope of the present disclosure.

The above-mentioned embodiments are merely several exemplary embodiments of the present disclosure, and the description is relatively specific and detailed, but it should not be understood as a limitation to the scope of the present disclosure. It should be noted that those of ordinary skill in the art can make several transformations and improvements without departing from the concept of the disclosure, and these all fall within the protection scope of the disclosure. Therefore, the scope of protection of the disclosure shall be subject to the appended claims.

What is claimed is:

1. A reverse conducting lateral insulated-gate bipolar transistor, comprising: a drift region formed on a substrate, a gate located on the drift region, an emitter region located on the drift region and adjacent to a side of the gate, and a collector region located on the drift region and away from a side of the gate: wherein:
two or more N-well regions arranged at intervals are provided on a side of the drift region on which the collector region is located;
a P-well region is provided between two adjacent N-well regions of the two or more N-well regions arranged at intervals;
a P+ contact region is provided on a N-well region;
an N+ contact region is provided on the P-well region; and
both the P+ contact region and the N+ contact region are electrically connected to a collector leading-out terminal.

2. The reverse conducting lateral insulated-gate bipolar transistor according to claim 1, wherein the two or more N-well regions arranged at intervals at least comprises a first N-well region and a second N-well region, the P-well region at least comprises a first P-well region provided between the first N-well region and the second N-well region, an area of the first N-well region is equal to an area of the second N-well region, and the first N-well region and the second N-well region are symmetrically arranged with respect to the first P-well region.

3. The reverse conducting lateral insulated-gate bipolar transistor according to claim 2, wherein the first N-well region, the first P-well region and the second N-well regions are arranged in sequence in a direction from the emitter region to the collector region.

4. The reverse conducting lateral insulated-gate bipolar transistor according to claim 1, wherein the N+ contact region is enclosed by the P-well region in a direction parallel to a plane on which the substrate is located.

5. The reverse conducting lateral insulated-gate bipolar transistor according to claim 1, wherein the N+ contact region comprises a first portion and a second portion, the first portion comprises a sidewall portion and a bottom portion, the sidewall portion extends in a direction perpendicular to a plane on which the substrate is located, the bottom portion is connected to the sidewall portion at a side of the bottom portion adjacent to the substrate, the second portion is connected to the sidewall portion at a side of the second portion away from the substrate, and a depth of the sidewall portion is greater than a depth of the second portion.

6. The reverse conducting lateral insulated-gate bipolar transistor according to claim 5, wherein the depth of the sidewall portion is greater than a depth of the P+ contact region.

7. The reverse conducting lateral insulated-gate bipolar transistor according to claim 5, wherein a trench is formed in the P-well region, and the sidewall portion and the bottom portion of the first portion are formed by doping a side surface and a bottom surface of the trench respectively.

8. The reverse conducting lateral insulated-gate bipolar transistor according to claim 7, wherein a filling structure is formed in the trench, and the second portion is located on the filling structure.

9. The reverse conducting lateral insulated-gate bipolar transistor according to claim 8, wherein a material of the filling structure comprises an insulating material and/or polysilicon.

10. The reverse conducting lateral insulated-gate bipolar transistor according to claim 1, wherein there exists a plurality of P-well regions, a plurality of N+ contact regions are respectively located in the plurality of P-well regions, and the plurality of N+ contact regions are arranged alternatively with the P+ contact regions in a direction parallel to a plane where the substrate is located.

11. The reverse conduction lateral insulated gate bipolar transistor according to claim 10, wherein the two or more N-well regions provided at intervals are arranged alternatively with the plurality of P-well regions in a direction parallel to a plane where the substrate is located.

12. The reverse conducting lateral insulated-gate bipolar transistor according to claim 1, wherein a potential barrier between the P-well region and the drift region is lower than a potential barrier between the P-well region and the N-well region.

13. The reverse conducting lateral insulated-gate bipolar transistor according to claim 1, further comprising a channel region located on the drift region and adjacent to a side of the drift region on which the gate is located, wherein the channel region forms a conductive channel, and the N-well region is spaced from the channel region to serve as an N-type buffer layer of the reverse conducting lateral insulated-gate bipolar transistor.

14. The reverse conducting lateral insulated-gate bipolar transistor according to claim 13, wherein a substrate ohmic contact region having a first conductivity type and a source ohmic contact region having a second conductivity type are provided in the channel region, and the source ohmic contact region is in contact with the channel region at a side of the source ohmic contact region facing the gate to induce a channel in the channel region.

15. The reverse conducting lateral insulated-gate bipolar transistor according to claim 1, further comprising a field oxide layer formed between the drift region and the gate, and the field oxide layer serves as an isolation field region between the drift region and the gate.
